(19) United States
(12) Patent Application Publication
(10) Pub. No.: US 2010/0223036 A1
(43) Pub. Date: Sep. 2, 2010

(54) Apparatus, Method and Simulation Objects for Simulation of the Image Formation in a Transmission Electron Microscope

(75) Inventors: Ozan Öktem, Sundbyberg (SE); Duccio Fanelli, Firenze (IT)

Correspondence Address: YOUNG & THOMPSON, 209 Madison Street, Suite 500, Alexandria, VA, 22314, US

(73) Assignee: SIDEC TECHNOLOGIES AB, Kista (SE)

(21) Appl. No.: 12/279,737

(22) PCT Filed: Feb. 16, 2007
(86) PCT No.: PCT/SE2007/000146

§ 371 Date: Feb. 11, 2009

Related U.S. Application Data
(60) Provisional application No. 60/774,185, filed on Feb. 17, 2006.

(51) Int. Cl. G06F 17/10; G06G 7/62; G06T 1/00; H01J 37/26

(52) U.S. Cl. 703/2; 703/13

(57) ABSTRACT

An apparatus and a method for simulating the behaviour of a TEM based on the first-order Born approximation, the method including the following steps:—providing at least one mathematical model of a virtual specimen;—simulating the image formation in the TEM when imaging the specimen, the simulation being based on a model for image formation which fully accounts for the wave nature of the electrons within the realm of the first order Born approximation and one model for the imaging properties of the TEM instrument. This is particularly suitable for use in solving the structure determination problem in ET.

### TECHNICAL FIELD

The invention relates to an apparatus and a method for simulating the image formation in a transmission electron microscope (TEM). It also relates to an apparatus and a method for reconstructing, by means of electron tomography, the scattering properties of a sample from images formed by means of a TEM.

### BACKGROUND

In many cases one needs to determine the scattering properties of a sample. One method is to use electron tomography (ET) where the sample is radiated by electrons from different directions in a TEM. Such data are then used in calculations in ET to provide a reconstruction of the sample. Ideally one would like to determine the high-resolution 3-dimensional structure of individual molecules within the sample. Currently X-ray crystallography is used for structural studies, and in successful cases it provides a high-resolution 3-dimensional structure. However, X-ray crystallography requires the sample to be very pure and in crystalline form. Moreover, the structure obtained is an average of several thousand copies of the molecule of interest. Hence, X-ray crystallography is not applicable in cases where the sample does not crystallize or in studies where the goal is to reveal differences in structural conformations of molecular assemblies and structural studies of larger assemblies and sub-cellular objects. ET is successfully used in such cases, despite its main drawback, namely that it only provides a low-resolution structure compared to X-ray crystallography. One critical success factor for ET is the resolution. Hence, in ET there is a strong strive to achieve a better solution in the structure determination problem, as this would enable studies of individual molecules with a higher resolution than what is possible today.

Many methods for solving the structure determination problem in ET are based on an iterative scheme where synthetic data are created using a model for image formation. For such methods, the model for image formation is an important factor that affects the quality of the reconstructions. The more accurate the model, the better the reconstruction. However, a more accurate model also requires longer computational time and more computational resources. Ideally, a model for image formation should capture the physically relevant phenomena occurring in TEM that affect the reconstruction quality in ET, while requiring reasonable computational resources and a reasonable execution time. This is especially critical in cases when the radiation dose is low and the desired resolution is below 1-2 nm.

### OBJECT OF THE INVENTION

It is an object of the present invention to provide a solution for simulating image formation in a TEM that is suitable within a reconstruction scheme in ET, with regard to the aspects mentioned above.

### SUMMARY OF THE INVENTION

Image formation in TEM is naturally divided in two separate parts. The first part deals with the electron-specimen interaction and is independent of the imaging properties of the TEM instrument itself. The second part deals with the influence from the TEM itself, especially the optics. A natural principle for simulating image formation is therefore to simulate the electron-specimen interaction and the imaging properties of the TEM instrument independently of each other.

The present invention achieves the object stated above by providing an apparatus for providing a simulation of TEM imaging of specimen, arranged to simulate the electron-specimen interaction and the imaging properties of the TEM instrument, independently of each other, said apparatus comprising
model means for providing at least one mathematical description of the scattering properties of a virtual specimen;
simulating means for receiving the mathematical description of the scattering properties of the virtual specimen from the model means as input data and simulating the image formation in the TEM, and using a first model for simulating the electron-specimen interaction and a second model for simulating the imaging properties of the TEM instrument, said apparatus being characterized in that in the first model simulating electron-specimen interaction, the scattered electron wave can be expressed as an explicit expression involving the mathematical description of the scattering properties of the virtual specimen and the incoming electron wave, wherein said first model fully accounts for the wave nature of the electrons within the realm of the validity of said expression.

The object is also achieved according to the invention by a method for simulating the behaviour of a TEM, said method comprising the following steps:
providing at least one mathematical description of the scattering properties of a virtual specimen;
simulating the image formation in the TEM with the mathematical description of the scattering properties of the virtual specimen as input using a first model for simulating the electron-specimen interaction and a second model for simulating the imaging properties of the TEM instrument, said method being characterized in that in the first model simulating electron-specimen interaction, the scattered electron wave can be expressed as an explicit expression involving the mathematical description of the scattering properties of the virtual specimen and the incoming electron wave, wherein said first model fully accounts for the wave nature of the electrons within the realm of the validity of said expression.

In a preferred embodiment, the simulating means is arranged to base the simulation on the scalar Schrödinger equation for modelling the electron-specimen interaction and the isoplanatic model for the microscope optics. In one embodiment, the first-order Born approximation is used in order to model the electron specimen interaction. This approximation holds for if the sample is a weak scatterer, which is the case for most unstained biological specimens in ET.

The simulator apparatus generates synthetic image data of the virtual object, said image data being an accurate approximation to what would result from imaging a physically real object having the same scattering properties as the virtual object.

The storage means may be arranged to store the virtual model semi-permanently, or to receive a model and store it temporarily for a particular simulation. Alternatively, a model generating means may be arranged to provide a virtual model to the simulating means.

Within the realm of the first-order Born approximation, the wave properties of the interaction are fully accounted for. The influence of the TEM itself, especially the optics, on the image formation is essential. The optics creates interference which in turn is the basis for image formation of weakly scattering objects. The invention makes use of a wave optics model for simulating this part of the image formation.

This simulator is particularly suitable for use in solving the structure determination problem in ET. The main reason is that the model for the image formation is based on an explicit closed form expression that relates the measured intensity with the function describing the scattering properties of the specimen. It is this function that one seeks to recover in ET.

Thus, the invention also relates to an apparatus for reconstructing, by means of electron tomography, the scattering properties of a sample from images formed by means of a transmission electron microscope, comprising

receiving means for receiving data from the sample in a TEM experiment,

an apparatus for providing a simulation of TEM imaging of a specimen according to the above, and

reconstruction means for reconstructing the structural properties of said sample from said TEM data using said simulation.

By using said simulation, the reconstructing apparatus can incorporate into the reconstruction information regarding how the imaging process itself affects the structural data. This can be used to obtain a more correct reconstruction with a higher resolution.

The invention is based on the insight that biological specimens in ET are usually weakly scattering, creating phase contrast rather than amplitude contrast. Hence, in modelling an ET experiment the wave nature of the electrons must be accounted for. Typically, this has been done before by applying the first order Born approximation to the wave formulation for the electrons and then taking the first term in the asymptotic expansion (as the wave length approaches zero) of the scattered wave. This yields a model for image formation that is solely based on the X-ray transform (projection). In the prior art, most of the attempts that have been made to refine the model have been concerned with the second part of image formation, which is to improve the description of the optical properties of the TEM and the effect of the detector. According to the invention, this second part is handled in the way known in the art.

According to the invention, the first part of image formation, concerning the electron-specimen interaction is governed by the scalar Schrödinger equation. Applying a linear model (the first order Born approximation) for the electron-specimen interaction and linearizing the quadratic intensity allows us to provide a closed form expression for the intensity generated by a single electron when the scattering potential of the specimen is given. The measured data is the obtained by adding the effect of the detector in the way known in the art.

The simulating apparatus can also be used in other applications, such as simulations of TEM imaging in material sciences. Moreover, the apparatus can also be used as a simulator for more general scattering experiments where the scatterer, i.e. the specimen, is a weak scatterer generating mainly phase contrast, and the scattered wave also passes through an optical system. Such experiments occur in phase contrast light microscopy of weakly scattering objects.

In another aspect of the present invention, a simulation object arranged in a computer readable storage medium is provided, formed by simulating image formation in a transmission electron microscope, i.e. TEM, with a mathematical description of the scattering properties of the virtual specimen as input using a first model for simulating the electron-specimen interaction and a second model for simulating the imaging properties of the TEM instrument, wherein in the first model simulating electron-specimen interaction, the scattered electron wave can be expressed as an explicit expression involving a mathematical description of the scattering properties of the virtual specimen and an incoming electron wave, wherein said first model substantially fully accounts for the wave nature of the electrons within the realm of the validity of said expression.

In yet another aspect of the present invention, a reconstructed object arranged in a computer readable storage medium is provided, formed by reconstruction of received transmission electron microscope, TEM, data about a sample from the TEM, wherein the reconstructed object is obtained by:

obtaining a simulation object according to claim 12,

reconstructing the scattering properties of said sample from said TEM data using said simulation object.

The invention can be combined with known methods for tomographic reconstruction, such as Comet, Tikhonov regularization, ART, or ML-EM methods.

### BRIEF DESCRIPTION OF THE DRAWINGS

In the following, the invention will be described in a non-limiting way and in more detail with reference to exemplary embodiments illustrated in the enclosed drawings, in which:

FIG. 1 is a simplified view of a TEM apparatus according to the present invention;

FIG. 2 illustrates schematically a simulating device according to the present invention; and

FIG. 3 illustrates schematically a method according to the present invention.

### DETAILED DESCRIPTION OF PREFERRED EMBODIMENTS

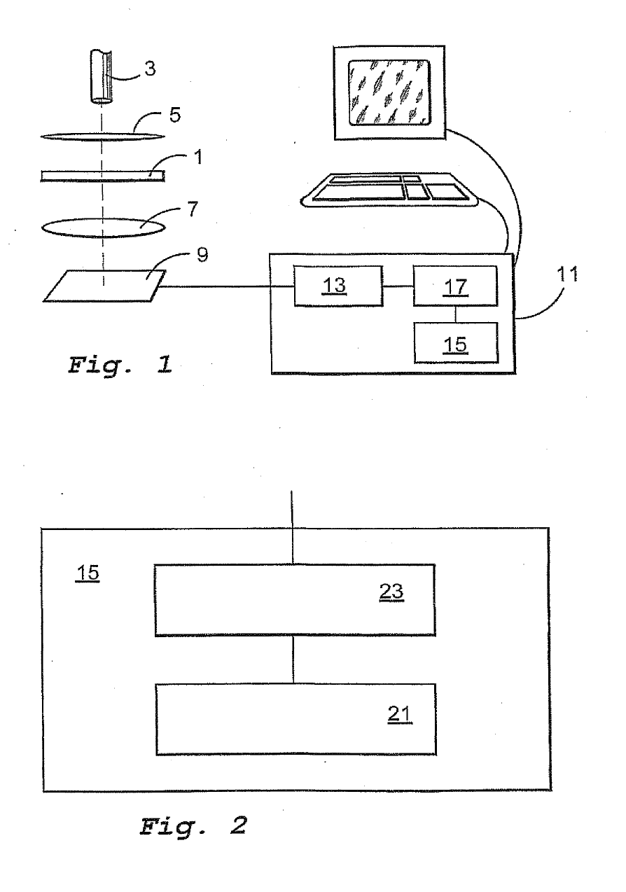

FIG. 1 illustrates schematically a transmission electron microscope (TEM) and a computer for calculating tomographic images of a sample, or specimen 1, that is imaged by the microscope. The function of the TEM is well known to the skilled person and is only outlined here. The TEM comprises an electron source 3 producing a stream of electrons. This electron stream is focused to a thin beam by means of condenser optics 5. The electrons strike the specimen 1 and are scattered. The scattered electrons pass through the objective (primary) lens and are focused on the focal plane. Some of these electrons are then transmitted through the aperture which is placed in the focal plane of the objective lens. The transmitted electrons then pass through the projector optics 7 and strike a detector 9, from which a recording is fed to a computer 11. The condenser, objective, and projector optics typically each include one or more electromagnetic lenses and apertures, which are not shown in detail here.

An image data receiving means 13 in the computer receives the recorded image data from the detector 9. The computer 11 also comprises a simulating device 15 arranged to simulate the behaviour of the components 3, 5, 7, 9 of the transmission electron microscope. An image reconstruction means 17 receives the image data from the receiving means 11 and information regarding the simulation from the simulating device 15. The discrepancy between the synthetic data obtained from the simulator and actual measured TEM data is used to compensate for the effects of the TEM itself when calculating the image. The image reconstruction means may for instance be a computational device such as a microprocessor, digital signal processor (DSP), FPGA (field programmable gate array), ASIC (application specific integrated circuit), or similar device capable of performing data analysis.

FIG. 2 illustrates a simulating device 15 according to the invention. The simulating device 15 comprises a model means 21 arranged to store on a computer readable medium or generate a model of a virtual object, in terms of its scattering properties, to be used in the simulation. The model means may receive the model from a source, which is typically but not necessarily located outside of the simulating device 15. The model means 21 provides the model to a simulator 23 arranged to provide a simulation of the virtual object. The computer readable storage medium may be of volatile or non-volatile type and may include but is not limited to any suitable type of RAM or a hard disk.

It should be appreciated that the reconstruction and model means may be located in an external device such as a computer as exemplified or as part of a TEM control system.

A preferred embodiment of the invention is based on the following assumptions and definitions.

The specimen is characterised by its electrostatic potential, which acts on the electrons. In TEM imaging of biological specimens that the following assumptions may be made
the scattering takes place in a field-free space.
there are no magnetic fields in the vicinity of the specimen, so electron spin and magnetic interaction between the electrons and the specimen can be ignored.

With these assumptions, the equation governing the electron-specimen interaction is the scalar Schrödinger wave equation. Hence, the scattered wave is the solution to this equation. The scattering properties of the specimen are captured by a complex valued function G, which is defined as

$$G ( \vec{x} ) := - \frac{2 m}{{ℏ}^{2}} ( V ( \vec{x} ) + i Λ ( \vec{x} ) ) for \vec{x} ∈ {3}^{} , \qquad ( 1 )$$

where
m represents the mass of the electron at rest
V is the real valued negative function denoting the potential energy
Λ is the real valued negative function denoting the absorption potential. This function actually has no proper physical interpretation in the strict sense. It is introduced in order to account for the loss of elastically scattered electrons due to inelastic scattering.

An arrow above a character indicates that the character denotes a vector.

Since the total potential energy V+iΛ is assumed to fulfil the Rollnick condition and it does not depend on time, one can look for stationary solutions of the form ψ(\vec{x},t)=u(\vec{x})e^{-iEt/h} where E is the constant energy of the elastically scattered electron. It is now relatively easy to show that in every source free domain in space [symbol] ³ (the specimen is especially source free), the time independent part u of the electron wave ψ fulfils the Helmholtz equation:

(∇²+k²nₖ(\vec{x}))u(\vec{x})=0 (2)

with suitable boundary conditions (the outgoing Sommerfeld radiation condition). Here k is the particle wave number with respect to the homogeneous background medium (which in this case is vacuum), and the relation between the wave number k and the wavelength λ is given by k=2π/λ. The complex valued function nₖ, which is called the index of refraction, is given as

nₖ(\vec{x}):=1+k⁻²G(\vec{x}). (3)

Note that the index of refraction is normalised to have unit value in the homogeneous background medium.

Now, with reference to FIG. 1, consider the following diffraction tomography experiment. We are given a fixed finite set S₀ ⊂ S² of directions, usually called tilt angles. For each direction \vec{ω} ∈ S₀ there is an associated optical system with optical axis \vec{ω}. We make use of the standard assumption in ET, where the optics of the microscope is simplified as to consist of a single thin lens, called the objective lens 7, with an aperture in its focal plane. Moreover, we use the convention that the objective lens 7 is in position \vec{ω}^{⊥}, the specimen 1 is in position −q+\vec{ω}^{⊥} with q always positive (so q denotes the distance from the specimen 1 to the lens 7 and the specimen 1 is placed in front of the optical system 7), and the detector 9 is in position r+\vec{ω}^{⊥} with r that is larger than the focal length of the objective lens (so the aperture is between the objective lens and the detector).

We also assume that the condenser 5 in the TEM provides us with perfect coherent illumination, i.e. we assume that the specimen 1 is probed by a monochromatic plane wave uⁱⁿ(\vec{x})=e^{ik\vec{x}·\vec{ω}} travelling in the \vec{ω}-direction. The incident wave is scattered by the specimen, the scattered wave then passes through the optics 7 of the microscope, and the resulting wave is measured in the detector 9. Hence, for each direction \vec{ω} ∈ S₀ we obtain the intensity Iₖ(G)(\vec{ω},\vec{z}+r\vec{ω}) which is measured for \vec{z} ∈\vec{ω}^{⊥} (note that when \vec{z} varies in \vec{ω}^{⊥}, then a \vec{z}+r\vec{ω} varies in the detector plane). This procedure of radiating the specimen with electrons and measuring the corresponding intensities is repeated for many choices of directions \vec{ω} ∈ S₀. The image simulation problem in TEM can now be stated as the problem of calculating the intensities Iₖ(G)(\vec{ω},\vec{z}+r\vec{ω}) for different choices of directions \vec{ω} ∈ S₀ and points \vec{z} ∈\vec{ω}^{⊥} on the detector plane, when the specimen G is given. In contrast, the structure determination problem in ET is the problem of determining the Coulomb potential V (which is the real part of G) from the data Iₖ(G)(\vec{ω},\vec{z}+r\vec{ω}) that are given for different directions \vec{ω} ∈ S₀ and points \vec{z} ∈\vec{ω}^{⊥} on the detector plane. The present invention is about solving the former problem, namely the image simulation problem in TEM.

As already mentioned, for each direction \vec{ω} ∈ S₀, the interaction between the incident wave (which is the monochromatic plane wave) and the specimen is described by the Helmholtz equation (2) above. The solution to this equation yields the scattered wave field, which is a non-linear function of G. If the specimen is a weak scatterer, which is the case in most biological TEM applications where ET is used, then the first order Born approximation can be applied, which linearizes the scattered wave field as a function of G. More precisely, using the first order Born approximation the scattered wave can be expressed as

u^{scatter}(\vec{x})≈uⁱⁿ(\vec{x})(1+k⁻¹Tₖ^{prop}(uⁱⁿ,G)(\vec{x})) (4)

where Tₖ^{prop} is the propagation operator which is well-known in diffraction tomography. This operator is the diffraction tomographic version of a projection (X-ray transform), and when one has coherent illumination (i.e. when uⁱⁿ(\vec{x})=e^{ik\vec{x}·\vec{ω}}), then by the generalised projection theorem in diffraction tomography one can easily deduce that

$${lim}_{k \to ∞} {T}_{k}^{prop} ( {u}^{in} , G ) ( \vec{x} - q \vec{ω} ) = iP ( G ) ( \vec{ω} , \vec{x} ) for \vec{x} ∈ {\vec{ω}}^{⊥} . \qquad ( 5 )$$

In the above formula, P(G) denotes the X-ray transform (projection) of G. Hence, the first order approximation of the propagation operator is given by the X-ray transform (projection). The scattered wave field now passes through the optics of the microscope, which acts as a linear transformation. Using the standard model in ET for the optics, this linear transformation can be expressed as a convolution in the detector plane. When the finite extent of the lens can be ignored and the optical system is aligned with respect to its optical axis, the point-spread functions PSFₖ^{re} and PSFₖ^{im}, that define the convolution that accounts for the optics in the TEM, are given as

$$\{ \begin{matrix}{PSF}_{k}^{re} ( \vec{ω} , \vec{y} ) = {F}_{{\vec{ω}}^{⊥}} \{ {x}_{Σ} ( \frac{f}{k} \cdot + f \vec{ω} ) sin [ {γ}_{k} ( {\vert \cdot \vert}^{2} ) ] \} ( \vec{y} ) \\ {PSF}_{k}^{im} ( \vec{ω} , \vec{y} ) = {F}_{{\vec{ω}}^{⊥}} \{ {x}_{Σ} ( \frac{f}{k} \cdot + f \vec{ω} ) cos [ {γ}_{k} ( {\vert \cdot \vert}^{2} ) ] \} ( \vec{y} )\end{matrix} \qquad ( 6 )$$

where \vec{y} ∈ \vec{ω}^{⊥} and
f denotes the focal length of the objective lens,
Σ defines the aperture in the focal plane (χ_{Σ} is the pupil function),
γₖ is the well-known function modelling the effects of defocus and aberration in the objective lens, and
F_{\vec{ω}}_{^{⊥}} denotes the Fourier transform in the \vec{ω}^{⊥}-plane.

Finally, the measured intensity is obtained by taking the square modulus of the resulting wave field. Here we assume that the intensity can be linearized. We can then obtain a closed form solution for the intensity generated by a single electron as a function of G:

$${I}_{k} ( G ) ( \vec{ω} , \vec{z} + r \vec{ω} ) = \frac{1}{{M}^{2}} ( \begin{matrix}1 - {( 2 π )}^{- 2} \\ [ \begin{matrix}\{ \begin{matrix}{PSF}_{k}^{re} ( \vec{ω} , \cdot ) {*}_{{\vec{ω}}^{⊥}} \\ Re [ {J}_{k , q} ( G ) ( \vec{ω} , \cdot ) ]\end{matrix} \} \\ ( \vec{z} / M ) + \\ \{ \begin{matrix}{PSF}_{k}^{im} ( \vec{ω} , \cdot ) {*}_{{\vec{ω}}^{⊥}} \\ Im [ {J}_{k , q} ( G ) ( \vec{ω} , \cdot ) ]\end{matrix} \} \\ ( \vec{z} / M )\end{matrix} ]\end{matrix} ) \qquad ( 7 )$$

where

$${J}_{k , q} ( G ) ( \vec{ω} , \vec{x} ) := \frac{1}{ik} {T}_{k}^{prop} ( {u}^{in} , G ) ( \vec{x} - q \vec{ω} )$$

when

$${u}^{in} ( \vec{x} ) = {e}^{i k \vec{x} \cdot \vec{ω}} , {*}_{{\vec{ω}}^{⊥}}$$

denotes the convolution in the \vec{ω}^{⊥}-plane, and M denotes the magnification of the microscope.

For completeness and clarity, the assumptions needed in order to derive the above formula (7) for the intensity are restated. Assumptions regarding the electron-specimen interaction are as follows:
1. The sample is a weak scatterer so the first order Born approximation holds.
2. The intensity can be linearized, i.e. the quadratic term can be ignored when considering the intensity as a function of G.

Assumptions regarding the optics read as follows:
1. The lens is very large compared to the specimen, so the finite extent of the lens can be ignored.
2. The optical system is aligned with respect to its optical axis, so the optical axis \vec{ω} passes through the aperture in the focal plane.
3. Perfect coherent illumination is assumed (that is, perfect temporal and spatial coherence). It can therefore be assumed that the incident wave is a monochromatic plane wave that propagates in the same direction as the optical axis, that is, uⁱⁿ(\vec{x})=e^{ik\vec{x}·\vec{ω}}.

The last assumption above regarding perfect coherent illumination can be relaxed by introducing envelope functions into the points spread functions. This technique is well-known in the ET community and can also be used here.

According to the above, in the model for electron-specimen interaction used according to the invention, the scattered electron wave can be expressed as an explicit expression involving the mathematical description of both the scattering properties of the virtual specimen and the incoming electron wave, said expression fully accounting for the wave nature of the electrons within the realm of the validity of the expression.

In contrast, as mentioned above, prior art methods for electron tomography are based on the following approximation:

$${lim}_{k \to ∞} {T}_{k}^{prop} ( {u}^{in} , G ) ( \vec{x} - q \vec{ω} ) = iP ( G ) ( \vec{ω} , \vec{x} ) for \vec{x} ∈ {\vec{ω}}^{⊥} . \qquad ( 8 )$$

This means that the wave properties of the electrons, even within the validity of the first order Born approximation, are not fully considered in the prior art models. Using the above approximation yields the following expression for the intensity generated by a single electron:

$${I}_{k} ( G ) ( \vec{ω} , \vec{z} + r \vec{ω} ) = ( \begin{matrix}1 - {( 2 π )}^{- 2} \\ [ \begin{matrix}\{ \begin{matrix}{PSF}_{k}^{re} ( \vec{ω} , \cdot ) {*}_{{\vec{ω}}^{⊥}} \\ P ( {G}^{re} ) ( \vec{ω} , - \cdot )\end{matrix} \} \\ ( \vec{z} / M ) + \\ \{ \begin{matrix}{PSF}_{k}^{im} ( \vec{ω} , \cdot ) {*}_{{\vec{ω}}^{⊥}} \\ P ( {G}^{im} ) ( \vec{ω} , - \cdot )\end{matrix} \} \\ ( \vec{z} / M )\end{matrix} ]\end{matrix} {k}^{- 1} ) + O ( {k}^{- 2} ) . \qquad ( 9 )$$

In the above expression, G^{re} and G^{im} are the real and imaginary parts, respectively, of G.

As we can see, the present state of the art models for image formation used in ET are based on replacing the real and imaginary parts of J_{k,q}(G)(\vec{ω},•) with k⁻¹P(G^{re})(\vec{ω},-•) and k⁻¹P(G^{im})(\vec{ω},-•), respectively, which are the projections of the real and imaginary parts of the potential defining the structure of the specimen. This replacement is motivated by an asymptotic development when the wave number k approaches infinity, i.e. when the wavelength approaches zero.

There are other methods that do not make use of the Born approximation and therefore constitute a more accurate model for the image formation. However, such methods all require quite high computational power and the computation of an image of a large three-dimensional structure typically takes several hours.

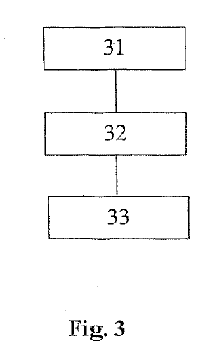

FIG. 3 illustrates a method for reconstructing, by means of electron tomography, the scattering properties of a sample from images formed by means of a TEM, comprising the steps of (31-33):
receiving TEM data about the sample from a TEM,
providing a simulation of TEM imaging of a specimen as claimed in any one of the claims 7-9,
reconstructing the scattering properties of the sample from the TEM data using the simulation.

It should be noted that the word “comprising” does not exclude the presence of other elements or steps than those listed and the words “a” or “an” preceding an element do not exclude the presence of a plurality of such elements. The invention can at least in part be implemented in either software or hardware. It should further be noted that any reference signs do not limit the scope of the claims, and that several “means”, “devices”, and “units” may be represented by the same item of hardware.

The above mentioned and described embodiments are only given as examples and should not be limiting to the present invention. Other solutions, uses, objectives, and functions within the scope of the invention as claimed in the below described patent claims should be apparent for the person skilled in the art.

1. An apparatus (15) for providing a simulation of TEM imaging of specimen, arranged to simulate the electron-specimen interaction and the imaging properties of the TEM instrument, independently of each other, said apparatus comprising:
model means (21) for providing at least one mathematical description of the scattering properties of a virtual specimen;
simulating means for receiving the mathematical description of the scattering properties of the virtual specimen from the model means as input data and simulating the image formation in the TEM, and using a first model for simulating the electron-specimen interaction and a second model for simulating the imaging properties of the TEM instrument, said apparatus being characterized in that said first model for simulating electron-specimen interaction is provided such that the scattered electron wave can be expressed as an explicit expression involving the mathematical description of the scattering properties of the virtual specimen and the incoming electron wave, wherein said first model substantially fully accounts for the wave nature of the electrons within the realm of the validity of the expression.

2. An apparatus according to claim 1, wherein the simulating means (23) is arranged to base the simulation on the scalar Schrδdinger equation for modelling the electron-specimen interaction and the isoplanatic model for the microscope optics.

3. An apparatus according to claim 2, wherein the first-order Born approximation is used in order to model the electron specimen interaction.

4. An apparatus according to claim 1, wherein the model means (21) is arranged to receive the model from a source and store it semipermanently.

5. An apparatus according to claim 1, wherein the model means (21) is arranged to receive the model from a source and store it temporarily for a particular simulation.

6. An apparatus according to claim 1, wherein the model means is arranged to generate the virtual model for a particular simulation.

7. A method for simulating the behaviour of a TEM, said method comprising the following steps:—using at least one mathematical description of the scattering properties of a virtual specimen;
simulating the image formation in the TEM with the mathematical description of the scattering properties of the virtual specimen as input using a first model for simulating the electron-specimen interaction and a second model for simulating the imaging properties of the TEM instrument, said method being characterized in that in the first model simulating electron-specimen interaction, the scattered electron wave can be expressed as an explicit expression involving the mathematical description of the scattering properties of the virtual specimen and the incoming electron wave, wherein said first model substantially fully accounts for the wave nature of the electrons within the realm of the validity of said expression.

8. A method for simulating the behaviour of the TEM according to claim 7, wherein the simulation is based on the scalar Schrδdinger equation for modelling the electron-specimen interaction and the isoplanatic model for the microscope optics.

9. A method according to claim 7, wherein the first-order Born approximation is used as a model for the electron specimen interaction.

10. An apparatus for reconstructing, by means of electron tomography, the structural properties of a sample from images formed by means of a transmission electron microscope, said apparatus comprising receiving means (13) for receiving TEM data about the sample from a TEM, an apparatus (15) for providing a simulation of TEM imaging of a specimen as claimed in claim 1, and reconstruction means (17) for reconstructing the scattering properties of said sample from said TEM data using said simulation.

11. A method for reconstructing, by means of electron tomography, the scattering properties of a sample from images formed by means of a TEM, comprising the steps of receiving TEM data about the sample from a TEM, providing a simulation of TEM imaging of a specimen as claimed in claim 7, reconstructing the scattering properties of said sample from said TEM data using said simulation.

12. A simulation object arranged in a computer readable storage medium, formed by simulating image formation in a transmission electron microscope, i.e. TEM, with a mathematical description of the scattering properties of the virtual specimen as input using a first model for simulating the electron-specimen interaction and a second model for simulating the imaging properties of the TEM instrument, wherein in the first model simulating electron-specimen interaction, the scattered electron wave can be expressed as an explicit expression involving a mathematical description of the scattering properties of the virtual specimen and an incoming electron wave, wherein said first model substantially fully accounts for the wave nature of the electrons within the realm of the validity of said expression.

13. A reconstructed object arranged in a computer readable storage medium, formed by reconstruction of received transmission electron microscope, TEM, data about a sample from the TEM, wherein the reconstructed object is obtained by: obtaining a simulation object according to claim 12, reconstructing the scattering properties of said sample from said TEM data using said simulation object.

14. A method according to claim 8, wherein the first-order Born approximation is used as a model for the electron specimen interaction.

15. A method for reconstructing, by means of electron tomography, the scattering properties of a sample from images formed by means of a TEM, comprising the steps of receiving TEM data about the sample from a TEM, providing a simulation of TEM imaging of a specimen as claimed in claim 8, reconstructing the scattering properties of said sample from said TEM data using said simulation.

16. A method for reconstructing, by means of electron tomography, the scattering properties of a sample from images formed by means of a TEM, comprising the steps of receiving TEM data about the sample from a TEM, providing a simulation of TEM imaging of a specimen as claimed in claim 9, reconstructing the scattering properties of said sample from said TEM data using said simulation.
